(19) United States
(12) Patent Application Publication
(10) Pub. No.: US 2026/0047170 A1
(43) Pub. Date: Feb. 12, 2026

(54) SEMICONDUCTOR DEVICE AND METHOD OF MANUFACTURING THE SAME

(71) Applicant: Renesas Electronics Corporation, Tokyo (JP)

(72) Inventor: Ryota KURODA, Tokyo (JP)

(21) Appl. No.: 19/241,963

(22) Filed: Jun. 18, 2025

(30) Foreign Application Priority Data
Aug. 7, 2024 (JP) 2024-131279

(51) Int. Cl. H10D 64/23; H10D 12/00; H10D 12/01

(52) U.S. Cl. CPC H10D 64/232; H10D 12/035; H10D 12/038; H10D 12/481

(57) ABSTRACT

An interlayer insulating film having an upper portion and a lower portion is formed on a first main surface of a semiconductor substrate. Furthermore, a contact hole penetrating the interlayer insulating film is formed, and a contact member is formed in the contact hole. In the cross-sectional view, the width of the contact hole in a first direction is wider at an upper end than at a lower end of the contact hole, and is wider at a depth corresponding to the upper portion of the interlayer insulating film than at a depth corresponding to the lower portion of the interlayer insulating film.

### CROSS-REFERENCE TO RELATED APPLICATIONS

The disclosure of Japanese Patent Application No. 2024-131279 filed on Aug. 7, 2024 including the specification, drawings and abstract is incorporated herein by reference in its entirety.

### BACKGROUND

The present invention relates to a semiconductor device and a method of manufacturing the same, and more particularly to a semiconductor device including a contact member formed in a contact hole and a method of manufacturing the same.

As an insulated gate bipolar transistor (IGBT) having a low collector-emitter saturation voltage VCE (sat), a trench gate IGBT is widely used. In order to further promote conductivity modulation, an IE type trench gate IGBT utilizing an injection enhancement (IE) effect has been developed.

There is an IE type trench gate IGBT in which an active cell actually connected to an emitter electrode and an inactive cell having a P type floating region are alternately arranged in a cell region. Thus, holes (electron holes) are easily accumulated on a device main surface side (emitter side) of the semiconductor substrate. In this type of the IE type trench gate IGBT, holes injected from a collector side are prevented from exiting to an emitter side by an inactive cell region, so that the concentration of holes between the active cell region and the collector side increases. When the concentration of holes increases, injection of electrons from the emitter (source) side is promoted, and the concentration of electrons also increases. In this way, conductivity modulation occurs due to an increase in carrier concentration (IE effect), and VCE (sat) can be lowered.

There is disclosed a technique listed below. [Patent Document 1] Japanese Unexamined Patent Application Publication No. 2019-29434

Further, the IE type trench gate IGBT includes a GE-S type IGBT including two trenches having different potentials of a trench (G) connected to a gate potential and a trench (E) connected to an emitter potential (for example, Patent Document 1). In the GE-S type IGBT, the P type floating region and a P type body region which is formed in the active cell region and to which the potential is supplied cannot be physically separated using the trench, and the electrical separation is performed using the high-concentration N type layer at a cell end portion.

### SUMMARY

In the IGBT of Patent Document 1, when a configuration of a conventional interlayer film (phospho silicate glass (PSG) single layer) is adopted as an interlayer insulating film, there is a problem that a waveform of a voltage-current characteristic with respect to a gate threshold voltage Vth becomes a kink waveform. The PSG film is an insulating film containing phosphorus, but it is considered that the phosphorus penetrates into the silicon substrate side in a heat treatment after the PSG formation, whereby a kink waveform is generated due to the influence of the layout peculiar to the GE-S type IGBT. Further, when a contact having a high aspect ratio is formed as a contact penetrating the interlayer insulating film, embeddability of a contact member such as tungsten may be deteriorated.

Other problems and novel features will become apparent from the description of the present specification and the accompanying drawings.

An outline of representative embodiments disclosed in the present application will be briefly described as follows.

In the semiconductor device according to the embodiment, an interlayer insulating film is formed on an upper side of a first main surface of a semiconductor substrate, a contact hole penetrating the interlayer insulating film is formed, and a contact member is formed in the contact hole. In the cross-sectional view, the width of the contact hole in a first direction is wider at an upper end than at a lower end of the contact hole, and is wider at a depth corresponding to the upper portion of the interlayer insulating film than at a depth corresponding to the lower portion of the interlayer insulating film.

A method of manufacturing a semiconductor device according to an embodiment includes: forming an interlayer insulating film having an upper portion and a lower portion on a first main surface of a semiconductor substrate; and forming a contact hole so as to penetrate the interlayer insulating film so that a contact member is in contact with a trench emitter electrode and the interlayer insulating film on one side in a first direction in cross-sectional view, and is in contact with a body region, an emitter region, and the interlayer insulating film on another side in the first direction, and forming the contact member in the contact hole. The step of forming the contact hole and the contact member includes forming the contact member in the contact hole so that a width of the contact hole in the first direction is wider at an upper end than at a lower end of the contact hole in cross-sectional view and is wider at a depth corresponding to the upper portion of the interlayer insulating film than at a depth corresponding to the lower portion of the interlayer insulating film by etching processing including first etching processing, second etching processing, and third etching processing, and forming the contact member in the contact hole.

According to an embodiment, the reliability of a semiconductor device can be improved.

### BRIEF DESCRIPTION OF THE DRAWINGS

FIG. 1 is a plan view illustrating an entire semiconductor device according to a first embodiment.

FIG. 2 is a cross-sectional view illustrating the semiconductor device according to the first embodiment.

FIG. 3 is a cross-sectional view (unit cell region) illustrating the semiconductor device according to the first embodiment.

FIG. 4 is a cross-sectional view illustrating a shape of a contact hole according to the first embodiment.

FIG. 5 is a cross-sectional view illustrating a manufacturing step of the semiconductor device according to the first embodiment.

FIG. 6 is a cross-sectional view illustrating a manufacturing step subsequent to the manufacturing step illustrated in FIG. 5.

FIG. 7 is a cross-sectional view illustrating a manufacturing step subsequent to the manufacturing step illustrated in FIG. 6.

FIG. 8 is a cross-sectional view illustrating a manufacturing step subsequent to the manufacturing step illustrated in FIG. 7.

FIG. 9 is a cross-sectional view illustrating a manufacturing step subsequent to the manufacturing step illustrated in FIG. 8.

FIG. 10 is a cross-sectional view illustrating a step of forming a contact hole in the first embodiment.

FIG. 11 is a cross-sectional view illustrating a forming step subsequent to the forming step illustrated in FIG. 10.

FIG. 12 is a cross-sectional view illustrating a forming step subsequent to the forming step illustrated in FIG. 11.

FIG. 13 is a cross-sectional view illustrating a forming step subsequent to the forming step illustrated in FIG. 12.

FIG. 14 is a cross-sectional view illustrating a forming step subsequent to the forming step illustrated in FIG. 13.

FIG. 15 is a cross-sectional view illustrating a shape of a contact hole according to a second embodiment.

FIG. 16 is a cross-sectional view illustrating a step of forming a contact hole in the second embodiment.

FIG. 17 is a cross-sectional view illustrating a forming step subsequent to the forming step illustrated in FIG. 16.

FIG. 18 is a cross-sectional view illustrating a forming step subsequent to the forming step illustrated in FIG. 17.

FIG. 19 is a cross-sectional view illustrating a forming step subsequent to the forming step illustrated in FIG. 18.

FIG. 20 is a cross-sectional view illustrating a forming step subsequent to the forming step illustrated in FIG. 19.

FIG. 21 is a cross-sectional view illustrating a shape of a contact hole according to a third embodiment.

FIG. 22 is a cross-sectional view illustrating a step of forming a contact hole in the third embodiment.

FIG. 23 is a cross-sectional view illustrating a forming step subsequent to the forming step illustrated in FIG. 22.

FIG. 24 is a cross-sectional view illustrating a forming step subsequent to the forming step illustrated in FIG. 23.

FIG. 25 is a cross-sectional view illustrating a forming step subsequent to the forming step illustrated in FIG. 24.

FIG. 26 is a cross-sectional view illustrating a forming step subsequent to the forming step illustrated in FIG. 25.

FIG. 27 is a cross-sectional view illustrating a shape of a contact hole according to a fourth embodiment.

FIG. 28 is a cross-sectional view illustrating a step of forming a contact hole the fourth embodiment.

FIG. 29 is a cross-sectional view illustrating a forming step subsequent to the forming step illustrated in FIG. 28.

FIG. 30 is a cross-sectional view illustrating a forming step subsequent to the forming step illustrated in FIG. 29.

FIG. 31 is a cross-sectional view illustrating a forming step subsequent to the forming step illustrated in FIG. 30.

FIG. 32 is a cross-sectional view illustrating a forming step subsequent to the forming step illustrated in FIG. 31.

### DETAILED DESCRIPTION

Hereinafter, each embodiment will be described with reference to the drawings. However, in the following description, the same components are denoted by the same reference numerals, and repeated description may be omitted. Note that, in order to make the description clearer, the drawings may schematically represent the width, thickness, shape, and the like of each part as compared with an actual aspect. Further, dimensional relationships of the respective elements, ratios of the respective elements, and the like do not necessarily coincide among the plurality of drawings. Note that, when a notation “N+ type” is used for an impurity region, “+” here means that impurity concentration is higher than that in an “N type” region, and when a notation “P+ type” is used, “+” here means that impurity concentration is higher than that in a “P type” region. When a notation “N− type” is used for an impurity region, “−” here means that impurity concentration is lower than that in an “N type” region, and when a notation “P− type” is used, “−” here means that impurity concentration is lower than that in a “P type” region.

### First Embodiment

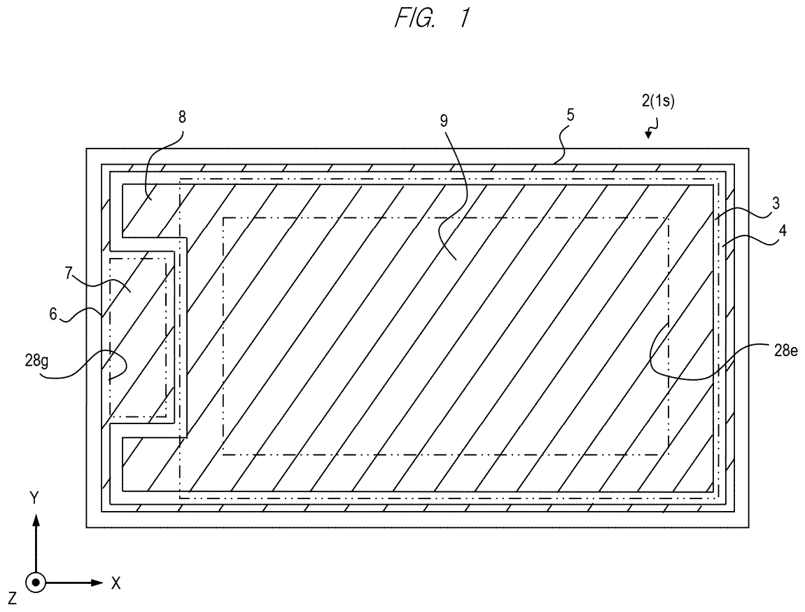

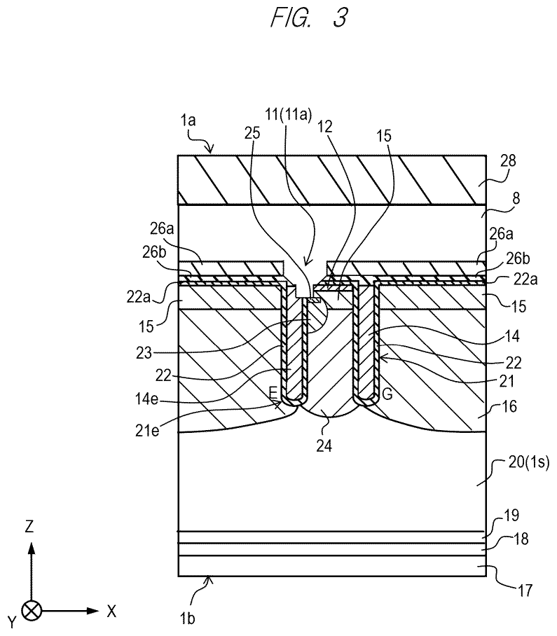

A configuration of a semiconductor device (semiconductor chip) according to a first embodiment will be described with reference to FIG. 1. FIG. 1 is a top view of a semiconductor device according to an embodiment. Note that, in FIG. 1, in order to simplify the understanding, an insulating film 28 (see FIG. 3) is removed and a transparent state is illustrated, and outer peripheries of a cell formation region 3, an emitter pad 9, and a gate pad 7 are indicated by two-dot chain lines. The semiconductor device illustrated in FIG. 1 is a GE-S type IGBT.

A semiconductor device 2 according to the embodiment includes a semiconductor substrate 1s. The semiconductor substrate 1s has a front surface as one main surface and a back surface opposite to the front surface as the other main surface. Further, the semiconductor substrate 1s has the cell formation region 3 as a partial region of the front surface and a gate wiring lead-out region 4 as a region of another portion of the front surface. The gate wiring lead-out region 4 is provided, for example, on an outer peripheral side of the semiconductor substrate 1s with respect to the cell formation region 3.

An emitter electrode 8 is provided in the cell formation region 3. A central portion of the emitter electrode 8 is an emitter pad 9 for connecting a bonding wire or the like. The emitter pad 9 includes the emitter electrode 8 in a portion exposed from an opening 28e formed in the insulating film 28 (see FIG. 3) formed so as to cover the emitter electrode 8. The emitter electrode 8 is constituted by, for example, a metal film whose main constituent is aluminum.

A gate wiring 5 and a gate electrode 6 are provided in the gate-wire lead-out region 4. The gate wiring 5 is provided, for example, on the outer peripheral side of the semiconductor substrate 1s with respect to the emitter electrode 8. The gate wiring 5 is connected to the gate electrode 6. A central portion of the gate electrode 6 is the gate pad 7 for connecting a bonding wire or the like. The gate pad 7 includes the gate electrode 6 in a portion exposed from an opening 28g formed in the insulating film 28 (see FIG. 3) formed so as to cover the gate electrode 6. The gate wiring 5 and the gate electrode 6 are constituted by, for example, a metal film whose main constituent is aluminum.

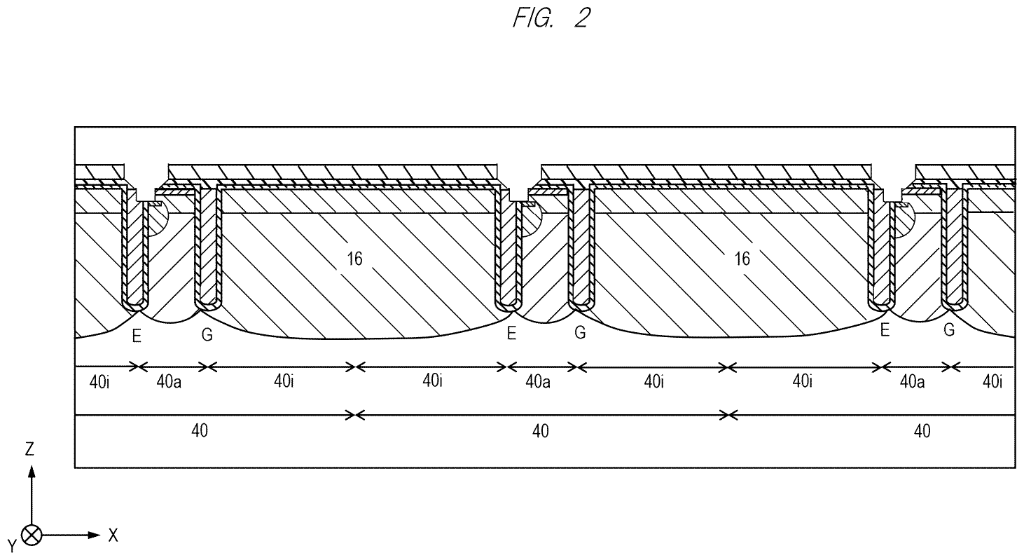

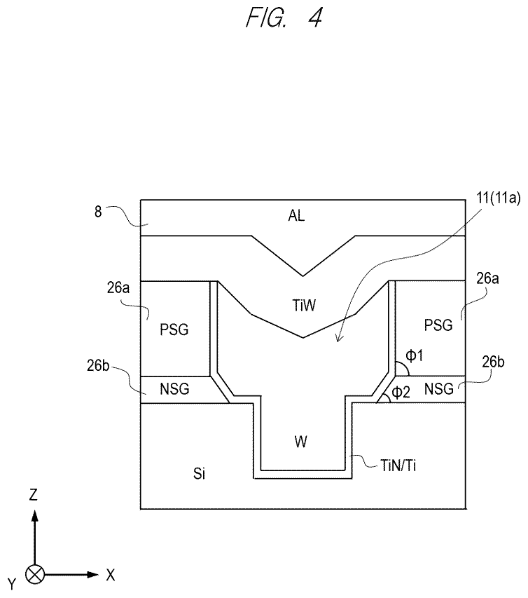

A configuration of the cell formation region of the semiconductor device 2 will be described with reference to FIGS. 2 and 3. FIG. 2 is a cross-sectional view of a cell formation region. FIG. 3 is a cross-sectional view (unit cell region) of the cell formation region illustrated in FIG. 2. FIG. 4 is a cross-sectional view illustrating a shape of a contact hole according to the first embodiment. Note that, in FIG. 2, in order to simplify the understanding, the insulating film 28 and the emitter electrode 8 illustrated in FIG. 3 are removed and the transparent state is illustrated.

As illustrated in FIG. 2, two directions intersecting with each other, preferably orthogonal to each other in the front surface of the semiconductor substrate 1s are defined as an X direction and a Y direction, and a direction perpendicular to the front surface of the semiconductor substrate 1s, that is, a vertical direction is defined as a Z direction. At this time, as illustrated in FIG. 2, a plurality of active cell regions 40a and a plurality of inactive cell regions 40i are provided in the cell formation region 3. The plurality of active cell regions 40a extend in the Y direction and are periodically arranged in the X direction in plan view. In other words, the active cell region 40a is formed in a longitudinal stripe shape. The plurality of inactive cell regions 40i extend in the Y direction and are periodically arranged in the X direction in plan view. Further, the active cell region 40a and the inactive cell region 40i are alternately arranged in the X direction. One active cell region 40a, a half region of the inactive cell region 40i adjacent to one side of the active cell region 40a, and a half region of the inactive cell region 40i adjacent to another side of the active cell region 40a constitute a unit cell region 40.

Note that, in the present specification, “in plan view” means a case of being viewed from a direction perpendicular to the front surface of the semiconductor substrate 1s.

In the active cell region 40a, a trench gate electrode 14 and a trench emitter electrode 14e illustrated in FIG. 3 are provided. The trench gate electrode 14 and the trench emitter electrode 14e extend in the Y direction in plan view. The trench gate electrode 14 and the trench emitter electrode 14e are provided on both sides in the X direction with a P type body region 15 and an N type hole barrier region 24 interposed therebetween. The trench gate electrode 14 is electrically connected to the gate electrode 6, and the trench emitter electrode 14e is electrically connected to the emitter electrode 8. The N type hole barrier region 24 is provided deeper than the P type body region 15.

In the active cell region 40a (see FIG. 2), a plurality of N+ type emitter regions 12 is provided in a portion of the P type body region 15 on the front surface side of the semiconductor substrate 1s. The P type body region 15 is a P type conductivity type semiconductor region, and the N+ type emitter region 12 is an N type conductivity type semiconductor region different from the P type conductivity type. In the active cell region 40a, the P type body region 15 is continuously formed along the Y direction in plan view. In the active cell region 40a, the plurality of N+ type emitter regions 12 is arranged at regular intervals from each other along the Y direction. Thus, an emitter width (S) can be reduced.

Note that, in the present specification, that the conductivity type of the semiconductor is P type means that only holes may be charge carriers, or both electrons and holes may be charge carriers, but the concentration of holes is higher than the concentration of electrons, and holes are main charge carriers. Further, in the present specification, that the conductivity type of the semiconductor is N type means that only electrons may be charge carriers, or both electrons and holes may be charge carriers, but the concentration of electrons is higher than the concentration of holes, and electrons are main charge carriers.

In the inactive cell region 40i (see FIG. 2), the P type body region 15 is provided between the trench gate electrode 14 and the trench emitter electrode 14e adjacent to each other. Further, a P type floating region 16 is provided deeper than the P type body region 15.

Further, in the example illustrated in FIG. 2, a width (Wa) of the active cell region 40a in the X direction is made narrower than a width (Wi) of the inactive cell region 40i in the X direction (Wa<Wi). In such a case, the IE effect of the IGBT can be enhanced.

In the gate wiring lead-out region 4, for example, there is a portion where the P type floating region 16 is provided so as to surround the cell formation region 3. Further, the P type floating region 16 is electrically connected to the emitter electrode 8 via a P+ type body contact region 25 of a portion exposed to a bottom surface of a contact hole 11.

Further, the gate wiring 5 is disposed in the gate wiring lead-out region 4 illustrated in FIG. 1, and the trench gate electrode 14 (see FIG. 3) extends from the inside of the cell formation region 3 toward the gate wiring 5. In the gate wiring lead-out region 4, end portions of the two trench gate electrodes 14 adjacent to each other are connected to each other and electrically connected to the gate wiring 5.

The trench gate electrode 14 and the trench emitter electrode 14e are arranged on both sides of an inactive cell region 40i (see FIG. 2) located between two active cell regions 40a adjacent to each other in plan view.

In the active cell region 40a (see FIG. 2), the P+ type semiconductor region including the P+ type body contact region 25 and a P+ type latch-up prevention region 23 illustrated in FIG. 3 is continuously formed along the Y direction. Further, in the active cell region 40a, the contact hole 11 as an opening is continuously formed along the Y direction in the P type body region 15 illustrated in FIG. 3. The contact hole 11 reaches the P+ type body contact region 25 disposed in the active cell region 40a.

Further, in the inactive cell region 40i (see FIG. 2) in the cell formation region 3 (see FIG. 2), the trench emitter electrode 14e is electrically connected to the emitter electrode 8.

As illustrated in FIG. 3, a P+ type collector region 18 is provided in a semiconductor region on a back surface of the semiconductor device 2, and a collector electrode 17 is provided on the front surface thereof. The collector electrode 17 is constituted by, for example, a metal film whose main constituent is aluminum. An N type field stop region 19 is provided between the N− type drift region 20 and the P+ type collector region 18 constituting the main part of the semiconductor substrate 1s.

On the N− type drift region 20 in the active cell region 40a, the N type hole barrier region 24, the P type body region 15, and an N+ type emitter region 12 are provided in this order from the bottom. The N+ type emitter region 12 is provided only on the trench gate electrode 14 side. Further, an interlayer insulating film (an upper portion 26a and a lower portion 26b) is formed on the trench gate electrode 14, the trench emitter electrode 14e, the P type body region 15, and the N+ type emitter region 12. The upper portion 26a of the interlayer insulating film is a phospho silicate glass (PSG) film, and the lower portion 26b of the interlayer insulating film is a non-doped silicate glass (NSG) film. The PSG film is an insulating film containing phosphorus, but by providing the NSG film under the PSG film in this manner, leakage of phosphorus to the semiconductor substrate 1s side can be prevented. The contact hole 11 extending into the trench emitter electrode 14e and the semiconductor substrate 1s is formed in the interlayer insulating film. A contact member 11a is embedded in the contact hole 11. The contact member 11a is in contact with the trench emitter electrode 14e and the interlayer insulating film (the upper portion 26a and the lower portion 26b) on the negative direction side of X, and is in contact with the P type body region 15, the N+ type emitter region 12, the P+ type body contact region 25 to be described later, and the interlayer insulating film (the upper portion 26a and the lower portion 26b) on the positive direction side of X. The contact member 11a includes a barrier metal film and a conductive film formed on the barrier metal film. The barrier metal film is, for example, a stacked film of a titanium film and a titanium nitride film formed on the titanium film. The conductive film is, for example, a tungsten film. The P+ type body contact region 25 and the P+ type latch-up prevention region 23 are provided in the semiconductor region at the bottom of the contact hole 11 and the like from above. The P type body region 15 and the N+ type emitter region 12 are connected to the emitter electrode 8 provided on the interlayer insulating film 26 via the contact hole 11 and the like.

Here, the N type hole barrier region 24 is a barrier region for preventing holes from flowing into a passage from the N− type drift region 20 to the N+ type emitter region 12. The impurity concentration of the N type hole barrier region 24 is lower than that of the N+ type emitter region 12 and higher than that of the N− type drift region 20. The presence of the N type hole barrier region 24 can effectively prevent holes accumulated in the inactive cell region 40i from entering an emitter passage (passage from the N− type drift region 20 toward the P+ type body contact region 25) of the active cell region 40a.

On the other hand, in the N− type drift region 20 in the inactive cell region 40i, the P type floating region 16 and the P type body region 15 are provided in order from the bottom. A depth of the P type floating region 16 is deeper than a depth of the trench 21. Further, the P type floating region 16 is distributed so as to cover a lower end portion of the trenches 21.

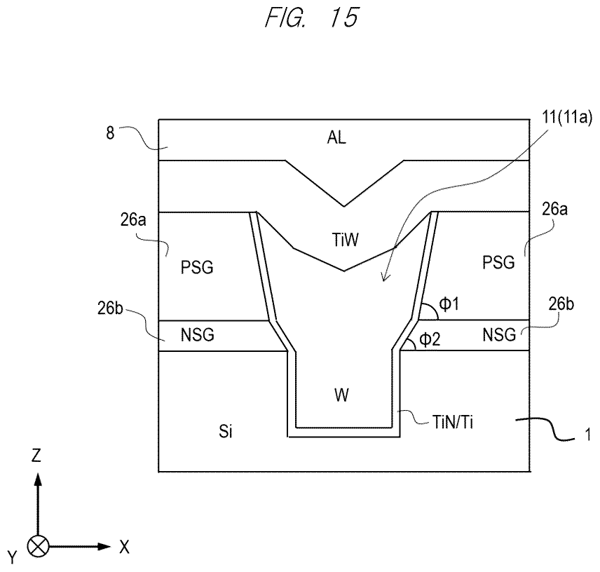

FIG. 4 is a cross-sectional view illustrating the shape of the contact hole 11 in the first embodiment (the gate insulating film 22 and the through insulating film for ion implantation 22a illustrated in FIG. 3 are omitted. The same applies to FIGS. 15, 21, and 27 described later). In the cross-sectional view, the width of the contact hole 11 in the X direction is wider at an upper end than at a lower end of the contact hole 11, and is wider at a depth corresponding to the upper portion 26a of the interlayer insulating film than at a depth corresponding to the lower portion 26b of the interlayer insulating film. Further, at the depth corresponding to the upper portion 26a of the interlayer insulating film, the inclination of the contact hole 11 is vertical or nearly vertical (inclination angle Φ (PHI)1 is 85 degrees to 90 degrees), whereas the inclination of the contact hole at the depth corresponding to the lower portion 26b is significantly smaller than vertical (inclination angle Φ (PHI)2 is significantly smaller than 90 degrees). By adopting such an inclination angle for the lower portion 26b of the interlayer insulating film, embeddability of tungsten in the contact member 11a can be improved. Further, by forming an upper portion of the contact hole 11 (a portion at the depth corresponding to the upper portion 26a of the interlayer insulating film) by dry etching so as to have the vertical or nearly vertical inclination angle Φ (PHI)1 as described in a manufacturing method to be described later, it is possible to suppress an increase in a contact hole diameter. Furthermore, phosphorus can be prevented from leaking from the PSG film (upper portion 26a) to the Si substrate side by forming the interlayer insulating film to have a two-layer structure of PSG/NSG.

### Method of Manufacturing Semiconductor Device in First Embodiment

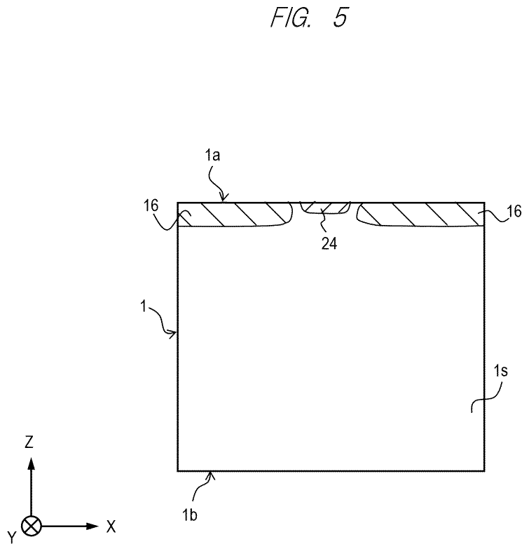

A method of manufacturing the semiconductor device 2 according to the first embodiment will be described with reference to FIGS. 5 to 9. FIGS. 5 to 9 are cross-sectional views illustrating a manufacturing process of the semiconductor device illustrated in FIG. 1. FIGS. 5 to 9 are cross-sectional views of the same cross section as the cross-sectional view of FIG. 3.

First, as illustrated in FIG. 5, a semiconductor wafer 1 constituted by a silicon single crystal semiconductor substrate 1s into which an N type impurity such as phosphorus is introduced is prepared. The semiconductor wafer 1 has a front surface 1a as a first main surface and a back surface 1b as a second main surface opposite to the front surface 1a.

Impurity concentration of the N type impurity in the semiconductor wafer 1 can be, for example, about 2×10¹⁴ cm⁻³. The thickness of the semiconductor wafer 1 can be, for example, about 450 μm (micrometers) to 1,000 μm (micrometers).

Next, an N type impurity is introduced into the semiconductor substrate 1s on the front surface 1a side of the semiconductor wafer 1 by an ion implantation method using a resist pattern as a mask, thereby forming the N type hole barrier region 24. As ion implantation conditions at this time, for example, ion implantation conditions in which the ion species is phosphorus, the dose amount is about 6×10¹² cm⁻², and the implantation energy is about 200 keV can be exemplified as suitable conditions.

Next, a P type impurity is introduced into the semiconductor substrate 1s on the front surface 1a side of the semiconductor wafer 1 by an ion implantation method using a resist pattern as a mask, thereby forming the P type floating region 16. As ion implantation conditions at this time, for example, ion implantation conditions in which the ion species is boron, the dose amount is about 3.5×10¹² cm⁻², and the implantation energy is about 75 keV can be exemplified as suitable conditions.

Note that the P type floating region 16 is formed in the inactive cell region 40i. Further, when the P type floating region 16 is formed in the cell formation region 3, for example, the P type floating region 16 is formed in the gate wiring lead-out region 4.

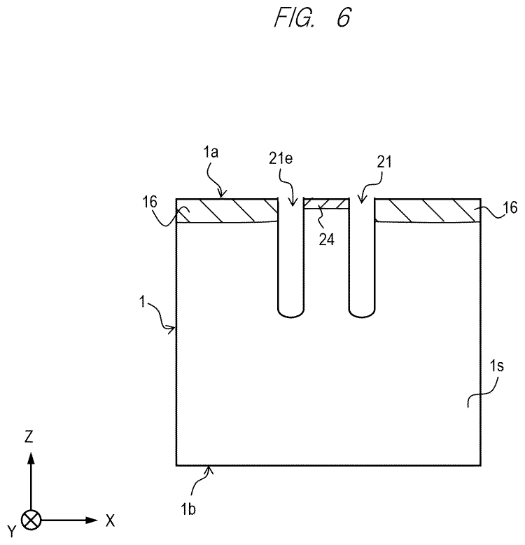

Next, as illustrated in FIG. 6, trenches 21 and 21e are formed by, for example, an anisotropic dry etching method using a hard mask constituted by, for example, a silicon oxide film. As the anisotropic dry etching gas, for example, a Cl₂/O₂-based gas can be exemplified as a suitable gas.

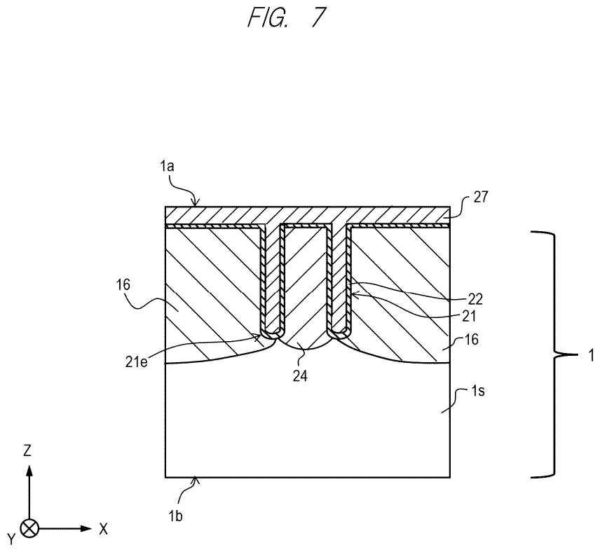

Next, as illustrated in FIG. 7, extension diffusion (for example, 1200° C. (1200 degrees Celsius), about 30 minutes) is performed on the P type floating region 16 and the N type hole barrier region 24. At this time, stretching and diffusion are performed so that an end portion of the P type floating region 16 on the back surface 1b side is arranged at an end portion of the trenches 21 and 21e on the back surface 1b side in the Z direction.

Next, the gate insulating film 22 constituted by, for example, a silicon oxide film is formed on the front surface 1a of the semiconductor wafer 1 and respective inner walls of the trenches 21 and 21e by, for example, a thermal oxidation method or the like. The thickness of the gate insulating film 22 is, for example, about 0.12 μm (micrometers).

The P type floating region 16 is formed between the trench 21 and the adjacent trench 21e by the extension and diffusion. Preferably, the P type floating region 16 is in contact with the gate insulating film 22 formed on the inner wall of the trench 21 and the gate insulating film 22 formed on the inner wall of the trench 21e.

Further, an N type hole barrier region 24 is formed between the trench 21 and the trench 21e. Preferably, the N type hole barrier region 24 formed between the trench 21 and the trench 21e is in contact with the gate insulating film 22 formed on the inner wall of the trench 21 and the gate insulating film 22 formed on the inner wall of the trench 21e.

Further, a region of the N type semiconductor wafer 1 where the P type floating region 16 and the N type hole barrier region 24 are not formed at the time of the stretching and diffusion becomes the N− type drift region 20.

Between the trench 21 and the trench 21e, the N type impurity concentration of the N type hole barrier region 24 is higher than the N type impurity concentration in the N− type drift region 20 and lower than the N type impurity concentration of the N+ type emitter region 12 described later.

Next, a conductive film 27 constituted by a doped poly-silicon film doped with phosphorus is formed on the front surface 1a of the semiconductor wafer 1 and inside the trenches 21 and 21e by, for example, a chemical vapor deposition (CVD) method or the like. The thickness of the conductive film 27 is, for example, about 0.5 μm to 1.5 μm.

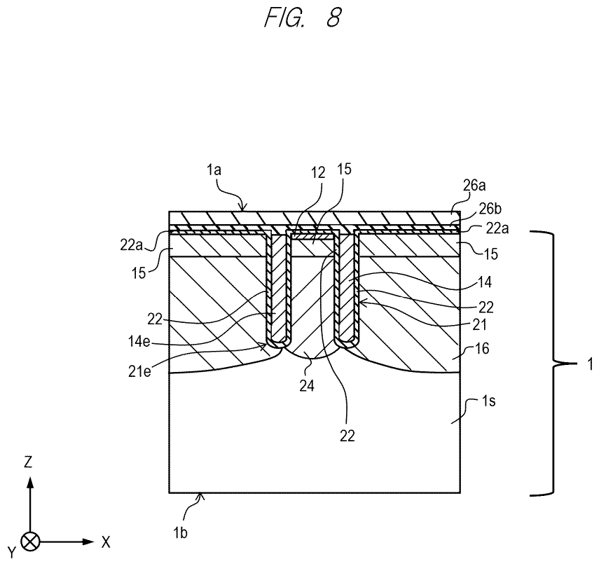

Next, as illustrated in FIG. 8, the conductive film 27 is etched back by, for example, a dry etching method. Thus, the trench gate electrode 14 constituted by the conductive film 27 embedded inside the trench 21 via the gate insulating film 22 is formed. Further, the trench emitter electrode 14e constituted by the conductive film 27 embedded inside the trench 21e via the gate insulating film 22 is formed. As this etching gas, for example, SF₆ gas or the like can be exemplified as a suitable gas.

Next, the gate insulating film 22 other than the inside of the trenches 21 and 21e is removed by, for example, a dry etching method.

Next, an insulating film 22a constituted by a relatively thin silicon oxide film for subsequent ion implantation is formed on the front surface 1a of the semiconductor wafer 1 by, for example, a thermal oxidation method or a CVD method. The insulating film 22a is formed to have a thickness of, for example, about several nm to 20 nm, and is used as a through film for ion implantation.

Next, P type impurities are introduced into the entire surface of the cell formation region 3 and other necessary portions by an ion implantation method using a resist pattern as a mask, thereby forming the P type body region 15.

Specifically, the P type body region 15 in contact with the gate insulating film 22 formed on the inner wall of the trench 21 and the gate insulating film 22 formed on the inner wall of the trench 21e is formed between the trench 21 and the trench 21e. The P type body region 15 is formed on the N type hole barrier region 24 in the active cell region 40a. Further, in the inactive cell region 40i, the P type body region 15 is formed on the P type floating region 16.

As ion implantation conditions at this time, for example, ion implantation conditions in which the ion species is boron, the dose amount is about 3×10¹³ cm⁻², and the implantation energy is about 75 keV can be exemplified as suitable conditions.

Further, an N type impurity is introduced into an upper layer portion of the P type body region 15 in the active cell region 40a by an ion implantation method using a resist pattern as a mask, thereby forming the N+ type emitter region 12.

As ion implantation conditions at this time, for example, ion implantation conditions in which the ion species is arsenic, the dose amount is about 5×10¹⁵ cm⁻², and the implantation energy is about 80 keV can be exemplified as suitable conditions.

Next, as illustrated in FIG. 8, an interlayer insulating film 26 including, for example, a PSG film (upper portion 26a) and an NSG film (lower portion 26b) is formed on the front surface 1a of the semiconductor wafer 1 by, for example, a CVD method or the like. The interlayer insulating film 26 is formed in each of the active cell region 40a and the inactive cell region 40i so as to cover the P type body region 15 via the insulating film 22a, for example. The thickness of the interlayer insulating film 26 is, for example, about 0.8 μm (micrometer) for the PSG film (upper portion 26a) and about 0.1 μm (micrometer) for the NSG film (lower portion 26b). As a material of the interlayer insulating film 26, in addition to the PSG film and the NSG film, a borophosphosilicate glass (BPSG) film, a spin-on-glass (SOG) film, a composite film thereof, or the like can be exemplified as being suitable.

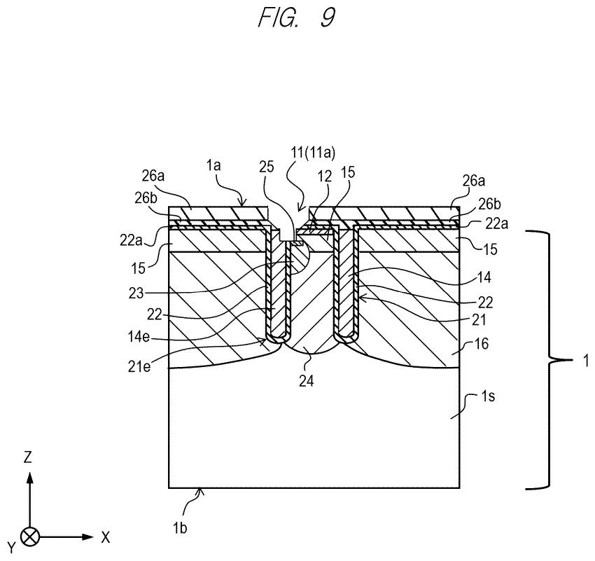

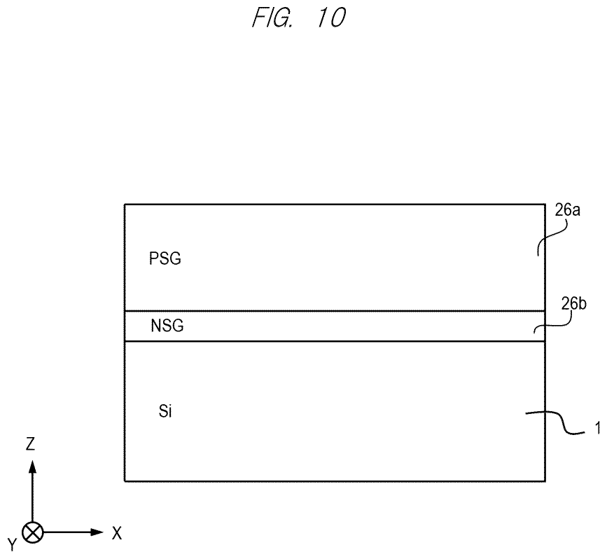

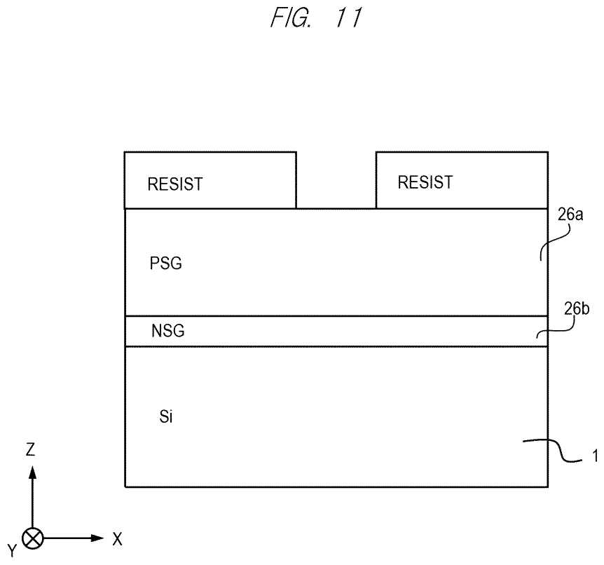

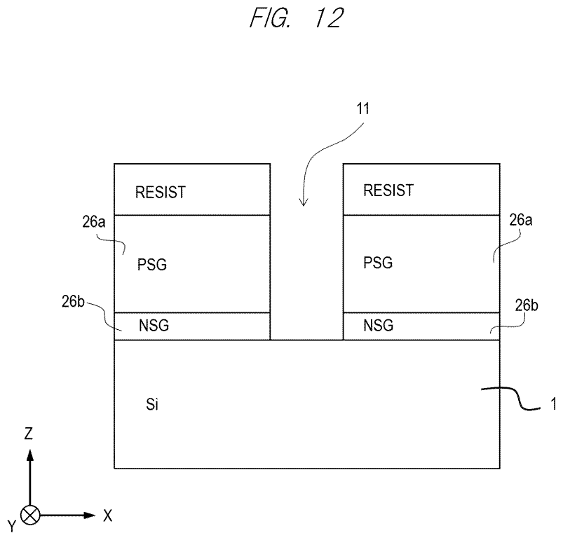

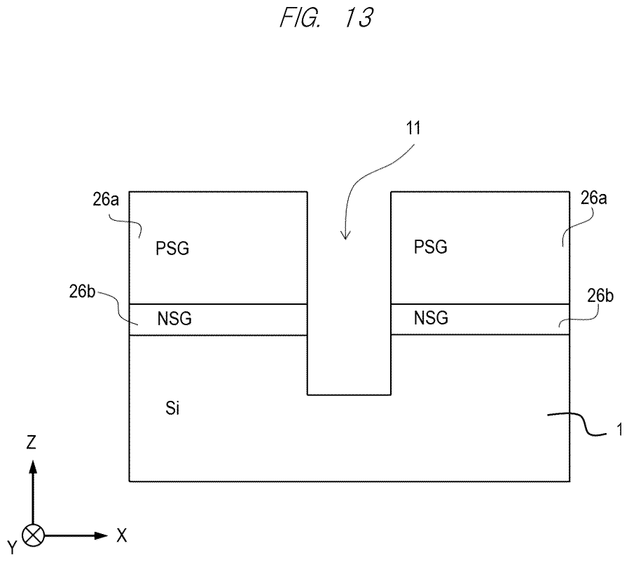

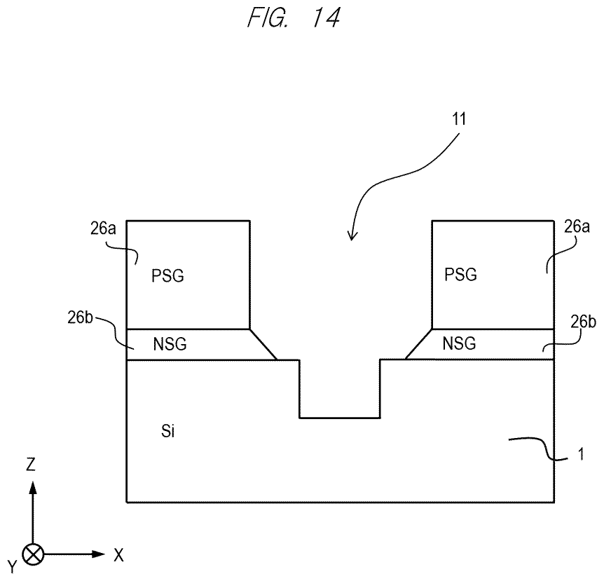

Next, by combining an anisotropic dry etching method using a resist pattern as a mask and an isotropic wet etching method, the contact hole 11 is formed in the interlayer insulating film (the upper portion 26a and the lower portion 26b) as illustrated in FIG. 9. Specifically, as illustrated in FIG. 10, the semiconductor wafer 1 on which the upper portion 26a and the lower portion 27b of the interlayer insulating film are formed (in FIGS. 10 to 14, 16 to 20, 22 to 26, and 28 to 32, the through insulating film for ion implantation 22a is omitted, and each element formed on the semiconductor wafer 1 by the process illustrated in FIG. 8 is also omitted) is coated with a resist (FIG. 11), and then photolithography is performed to perform anisotropic dry etching processing, thereby forming the contact hole 11 (FIG. 12). As the anisotropic dry etching gas, for example, a mixed gas including an Ar gas, a CHF₃ gas, a CF₄ gas, an O₂ gas, or the like can be exemplified as a suitable gas. The anisotropic dry etching process is also performed on a silicon region to extend the contact hole 11 (FIG. 13). As this anisotropic dry etching gas, for example, Cl₂/O₂ gas can be exemplified as a suitable gas. Further, for example, by performing a wet etching process using a solution containing hydrofluoric acid (FIG. 14), the contact hole 11 having the shape illustrated in FIG. 9 is formed.

Next, the P+ type body contact region 25 is formed by ion-implanting a P type impurity through the contact hole 11, for example. As ion implantation conditions at this time, for example, ion implantation conditions in which the ion species is boron, the dose amount is about 5×10¹⁵ cm⁻², and the implantation energy is about 80 keV can be exemplified as suitable conditions.

Next, the P+ type latch-up prevention region 23 is formed by ion-implanting a P type impurity through the contact hole 11, for example. As ion implantation conditions at this time, for example, ion implantation conditions in which the ion species is boron, the dose amount is about 1×10¹⁵ cm⁻², and the implantation energy is about 100 keV can be exemplified as suitable conditions. The P type impurity concentration in the P+ type body contact region 25 is higher than the P type impurity concentration in the P+ type latch-up prevention region 23.

In the active cell region 40a (see FIG. 2), the P+ type body contact region 25 and the P+ type latch-up prevention region 23 are formed in a portion of the P type body region 15 exposed to the contact hole 11. That is, the P+ type body contact region 25 in contact with the P type body region 15 and the P+ type latch-up prevention region 23 are formed in a portion located between the trench 21 and the trench 21e. In the active cell region 40a, the P type impurity concentration in the P+ type body contact region 25 and the P+ type latch-up prevention region 23 is higher than the P type impurity concentration in the P type body region 15.

Next, a contact member 11a is formed inside the contact hole 11. First, a barrier metal film is formed inside the contact hole 11 and on the interlayer insulating film. The barrier metal film can be formed by, for example, forming a titanium film inside the contact hole 11 and on the interlayer insulating film by a sputtering method, and forming a titanium nitride film on the titanium film by a sputtering method.

Next, a conductive film constituted by, for example, a tungsten film is formed on the barrier metal film by, for example, a CVD method so as to fill the inside of the contact hole 11. Next, the conductive film and the barrier metal film formed outside the contact hole 11 are removed by anisotropic etching processing. Thus, the contact member 11a is formed so as to embed the inside of the contact hole 11.

Next, as illustrated in FIG. 3, the emitter electrode 8 is formed. Specifically, for example, the processing is performed in the following procedure. First, a titanium tungsten film is formed as a barrier metal film on the front surface 1a of the semiconductor wafer 1 by, for example, a sputtering method. The thickness of the titanium tungsten film is, for example, about 0.2 μm (micrometer).

Next, for example, silicide annealing at about 600° C. (600° C.) for about 10 minutes is performed in a nitrogen atmosphere. Thereafter, an aluminum-based metal film (for example, several % silicon is added, and the rest is aluminum) is formed on the entire surface of the barrier metal film by, for example, a sputtering method. The thickness of the aluminum-based metal film is, for example, about 5 μm (micrometers).

Next, the emitter electrode 8 constituted by an aluminum-based metal film and a barrier metal film is formed by a dry etching method using a resist pattern as a mask. As this dry etching gas, for example, Cl₂/BCl₃ gas or the like can be exemplified as a suitable gas.

The emitter electrode 8 is electrically connected to the plurality of N+ type emitter regions 12, the plurality of P+ type body contact regions 25, and the P+ type latch-up prevention region 23 formed in the active cell region 40a (see FIG. 2).

Note that, when the emitter electrode 8 is formed, the gate electrode 6 electrically connected to the trench gate electrode 14 may be formed (see FIG. 1). In addition, when the emitter electrode 8 is formed in the cell formation region 3, the gate wiring 5 and the gate electrode 6 may be formed in the gate wiring lead-out region 4 (see FIG. 1).

Next, the insulating film 28 (see FIG. 3) as a passivation film constituted by, for example, an organic film containing polyimide as a main component is formed on the emitter electrode 8. The thickness of the insulating film 28 is, for example, about 10.0 μm (micrometers).

Next, the insulating film 28 is patterned by a dry etching method using a resist pattern as a mask to form an opening 28e that penetrates the insulating film 28 and reaches the emitter electrode 8 (see FIG. 1). Then, the emitter pad 9 constituted by the emitter electrode 8 at the portion exposed to the opening 28e is formed (see FIG. 1).

Note that, when the insulating film 28 is formed on the emitter electrode 8 in the cell formation region 3, the insulating film 28 is formed on the gate electrode 6 in the gate-wire lead-out region 4 (see FIG. 1). Further, when the opening 28e is formed in the cell formation region 3, an opening 28g that penetrates the insulating film 28 and reaches the gate electrode 6 is formed in the gate wiring lead-out region 4. Then, the gate pad 7 constituted by the portion of the gate electrode 6 exposed to the opening 28g is formed (see FIG. 1).

Next, the back surface 1b (see FIG. 5) of the semiconductor wafer 1 (see FIG. 5) is subjected to back grinding processing to thin the thickness of, for example, about 800 μm (micrometers) to, for example, about 30 μm (micrometers) to 200 μm (micrometers) as necessary. For example, when the withstand voltage is about 600 V, the final thickness is about 70 μm (micrometer). Further, chemical etching or the like for removing damage on the back surface 1b is also performed as necessary.

Next, an N type impurity is introduced into the back surface 1b of the semiconductor wafer 1 by, for example, an ion implantation method to form an N type field stop region 19 (see FIG. 3). As ion implantation conditions at this time, for example, ion implantation conditions in which the ion species is phosphorus, the dose amount is about 7×10¹² cm⁻², and the implantation energy is about 350 keV can be exemplified as suitable conditions. Thereafter, laser annealing or the like is performed on the back surface 1b of the semiconductor wafer 1 for impurity activation as necessary.

Next, a P+ type collector region 18 (see FIG. 3) is formed by introducing a P type impurity into the back surface 1b of the semiconductor wafer 1 by, for example, an ion implantation method. As ion implantation conditions at this time, for example, ion implantation conditions in which the ion species is boron, the dose amount is about 1×10¹³ cm⁻², and the implantation energy is about 40 keV can be exemplified as suitable conditions. Thereafter, laser annealing or the like is performed on the back surface 1b of the semiconductor wafer 1 for impurity activation as necessary.

Next, the collector electrode 17 (see FIG. 3) electrically connected to the P+ type collector region 18 is formed on the back surface 1b of the semiconductor wafer 1 by, for example, a sputtering method. Thereafter, the semiconductor substrate 1s is divided into chip regions by dicing or the like, and sealed in a package as necessary, thereby substantially completing the semiconductor device 2.

Here, in order to more specifically exemplify the device structure, an example of main dimensions of each part of the device (see FIGS. 2 and 3) will be described. That is, the width (Wa) of the active cell region 40a is about 0.8 μm (micrometers) to 0.9 μm (micrometers), and the width (Wi) of the inactive cell region 40i is about 3.3 μm (micrometers). The width (Wa) of the active cell region 40a is desirably narrower than the width (Wi) of the inactive cell region 40i, and the value of Wi/Wa is particularly preferably, for example, in a range of 2 to 3. The contact width is about 0.7 μm (micrometers) (the width of the lower end of the contact hole 11) to 0.9 μm (micrometers) (the width of the upper end of the contact hole 11), the trench width is about 0.4 μm (micrometers) to 0.5 μm (micrometers), and the trench depth is about 3 μm (micrometers). The depth of the N+ type emitter region 12 is about 250 nm, the depth of the P type body region 15 (channel region) is about 0.8 μm (micrometer), and the depth of the P+ type latch-up prevention region 23 is about 1.4 μm (micrometer). The depth of the P type floating region 16 is about 4.5 μm (micrometers), the thickness of the N type field stop region 19 is about 1.5 μm (micrometers), the thickness of the P+ type collector region is about 0.5 μm (micrometers), and the thickness of the semiconductor substrate 1s is about 70 μm (micrometers). Here, an example is illustrated in which the thickness of the semiconductor substrate 1s is about a withstand voltage of 600 volts. Note that the thickness of the semiconductor substrate 1s strongly depends on the required withstand voltage. Therefore, the withstand voltage of 1200 volts is, for example, about 120 μm (micrometers), and the withstand voltage of 400 volts is, for example, about 40 μm (micrometers). Note that these numerical values are merely examples.

Hereinafter, second to fourth embodiments will be described. In the following description of the embodiment, it is assumed that the same reference numerals as those in the first embodiment can be used for portions having the same configurations and functions as those described in the first embodiment. For the description of such a portion, the description in the first embodiment described above can be appropriately incorporated within a scope not technically contradictory. Further, a part of the above-described first embodiment and all or a part of the second to fourth embodiments can be applied in a combined manner as appropriate within a range not technically contradictory.

### Second Embodiment

FIG. 15 is a cross-sectional view illustrating a shape of a contact hole according to the second embodiment. In a semiconductor device 2 of the second embodiment (the plan view is similar to FIG. 1), the configuration other than a shape of a contact hole 11 is basically similar to that of the first embodiment. In FIG. 15, in the cross-sectional view, a width of the contact hole 11 in the X direction is wider at an upper end than at a lower end of the contact hole 11, and is wider at a depth corresponding to an upper portion 26a of the interlayer insulating film than at a depth corresponding to a lower portion 26b of the interlayer insulating film. An inclination angle Φ (PHI)1 of the contact hole 11 at the depth corresponding to the upper portion 26a of the interlayer insulating film is larger than an inclination angle Φ (PHI)2 of the contact hole 11 at the depth corresponding to the lower portion 26b. In other words, in the cross-sectional view, the width of the contact hole 11 in the X direction is enlarged at the depth corresponding to the lower portion 26b of the interlayer insulating film and the depth corresponding to the upper portion 26a of the interlayer insulating film in a direction from an inside of the semiconductor wafer 1 toward the front surface 1a (see FIG. 5) along the Z direction, and an enlargement ratio at the depth corresponding to the lower portion 26b of the interlayer insulating film is larger than an enlargement ratio at the depth corresponding to the upper portion 26a of the interlayer insulating film. As described above, as an effect other than the effect described in the first embodiment, a barrier metal film (TiN/Ti) can be thickened and barrier performance can be enhanced by providing the inclination also at the upper portion 26a of the interlayer insulating film. Further, by making Φ (PHI)1 larger than Φ (PHI)2, an increase in the contact diameter can be suppressed.

### Method of Manufacturing Semiconductor Device in Second Embodiment

The method of manufacturing the semiconductor device 2 according to the second embodiment is the same as that of the first embodiment except for the steps involved in the formation of the contact hole 11. Hereinafter, portions different from those of the first embodiment will be described.

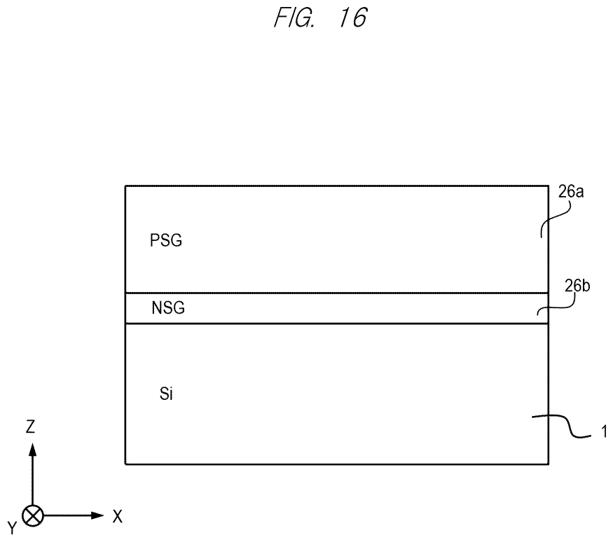

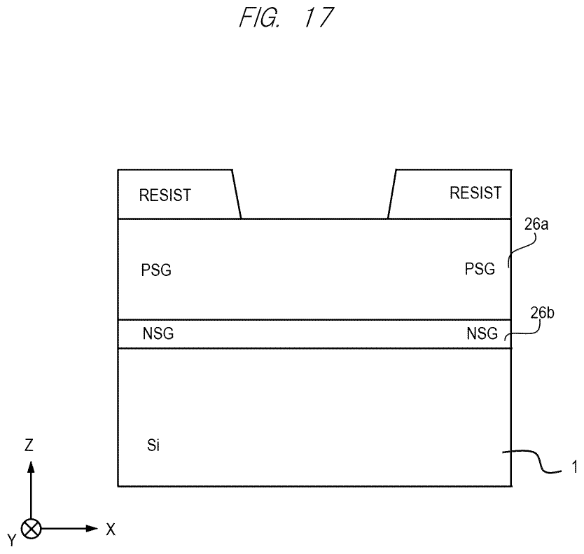

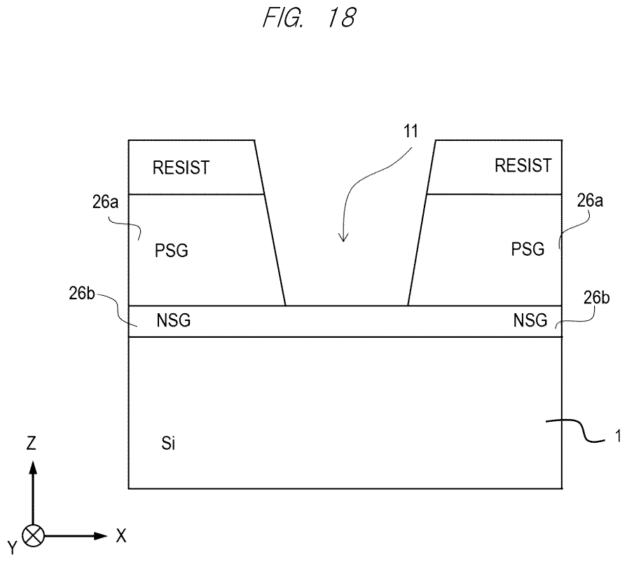

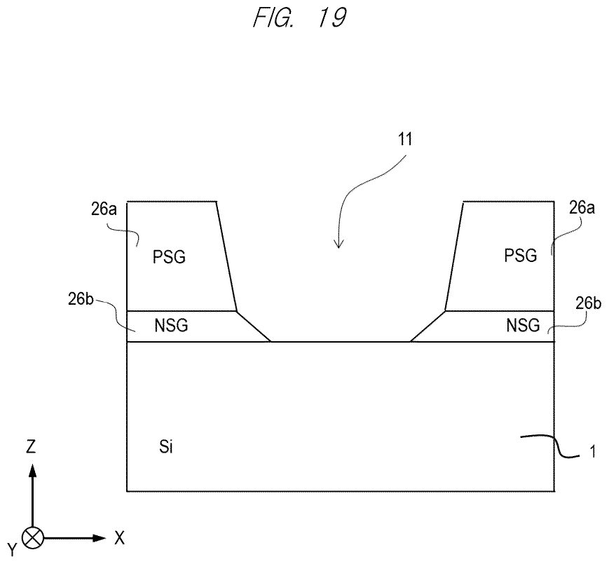

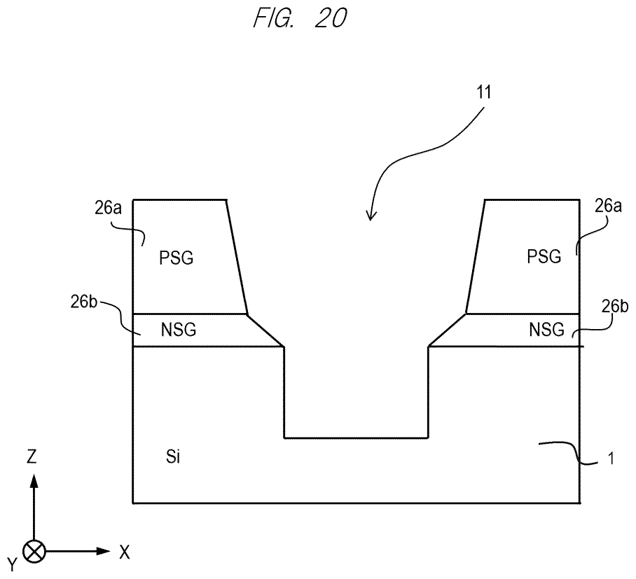

As illustrated in FIG. 16, a resist is applied (FIG. 17) to the semiconductor wafer 1 on which the upper portion 26a and the lower portion 26b of the interlayer insulating film are formed, and then, photolithography is performed, and an anisotropic dry etching process is performed to form a contact hole 11 (FIG. 18). The anisotropic dry etching process is stopped up to the upper portion 26a without etching up to the lower portion 26b of the interlayer insulating film. As the anisotropic dry etching gas, for example, a mixed gas including an Ar gas, a CHF₃ gas, a CF₄ gas, an O₂ gas, or the like can be exemplified as a suitable gas. Furthermore, an anisotropic dry etching process in which etching conditions are changed, for example, a flow rate ratio of an etching gas (O₂ or the like) is changed, is performed on the lower portion 26b of the interlayer insulating film (FIG. 19). Note that the inclination of the contact hole 11 can be adjusted by changing conditions such as a stage temperature and high frequency output in addition to changing the flow rate ratio of the etching gas. Adjusting the inclination of the contact hole 11 by changing the etching conditions is also performed in Examples 3 and 4 described later. The anisotropic dry etching process is also performed on a silicon region to extend the contact hole 11 (FIG. 20). As this anisotropic dry etching gas, for example, Cl₂/O₂ gas can be exemplified as a suitable gas.

### Third Embodiment

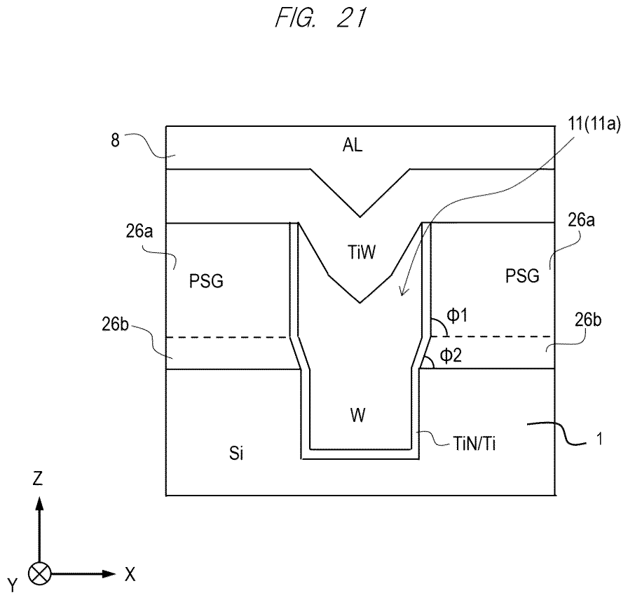

FIG. 21 is a cross-sectional view illustrating a shape of a contact hole according to a third embodiment. In a semiconductor device 2 of the third embodiment (the plan view is similar to FIG. 1), both the upper portion 26a and the lower portion 26b of the interlayer insulating film are PSG films and are integrated. The shape of a contact hole 11 is similar to that of the first embodiment. In the cross-sectional view, the width of the contact hole 11 in the X direction is wider at an upper end than at a lower end of the contact hole 11, and is wider at a depth corresponding to the upper portion 26a of the interlayer insulating film than at a depth corresponding to the lower portion 26b of the interlayer insulating film. Further, at the depth corresponding to the upper portion 26a of the interlayer insulating film, the inclination of the contact hole 11 is vertical or nearly vertical (inclination angle Φ (PHI)1 is 85 degrees to 90 degrees), whereas the inclination of the contact hole at the depth corresponding to the lower portion 26b is significantly smaller than vertical (inclination angle Φ (PHI)2 is significantly smaller than 90 degrees). By adopting such an inclination angle for the lower portion 26b of the interlayer insulating film, embeddability of tungsten in the contact member 11a can be improved. Further, by forming an upper portion of the contact hole 11 (a portion at the depth corresponding to the upper portion 26a of the interlayer insulating film) by dry etching so as to have the vertical or nearly vertical inclination angle Φ (PHI)1 as described in a manufacturing method to be described later, it is possible to suppress an increase in a contact hole diameter. Furthermore, by forming the interlayer insulating film as a single layer of the PSG film, it is not necessary to switch film forming conditions in the PSG film forming apparatus, and thus manufacturing cost is reduced.

### Method of Manufacturing Semiconductor Device in Third Embodiment

The method of manufacturing the semiconductor device 2 according to the third embodiment is the same as that of the first embodiment except for the steps involved in the formation of the interlayer insulating film and the formation of the contact hole 11. The interlayer insulating film (the upper portion 26a and the lower portion 26b) is formed by forming a PSG film by, for example, a CVD method or the like. Hereinafter, portions relating to the formation of the contact hole 11 different from those in the first embodiment will be described.

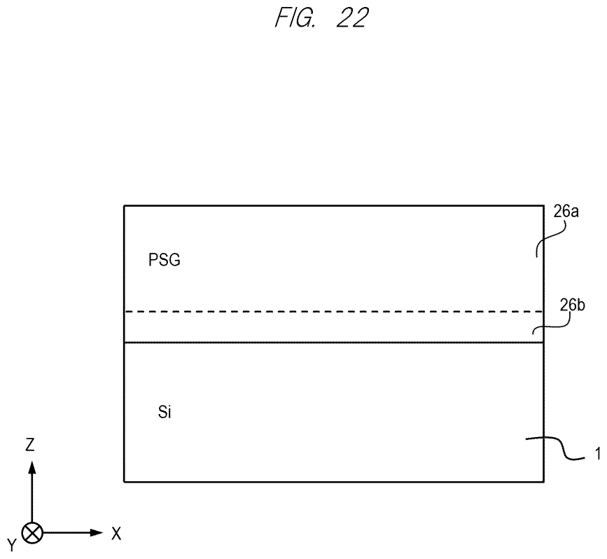

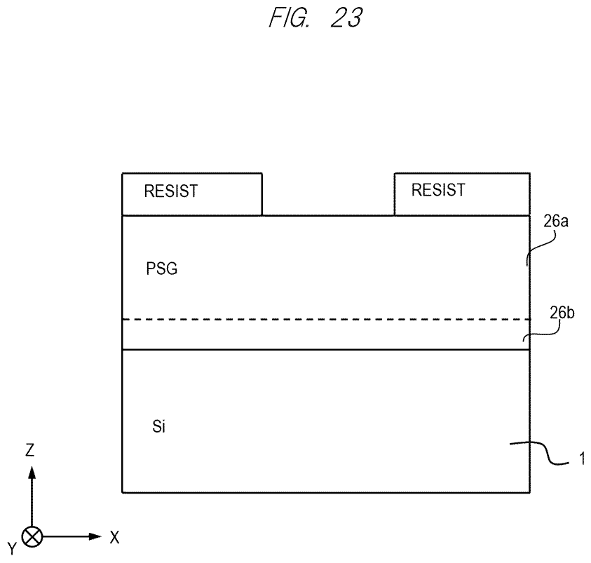

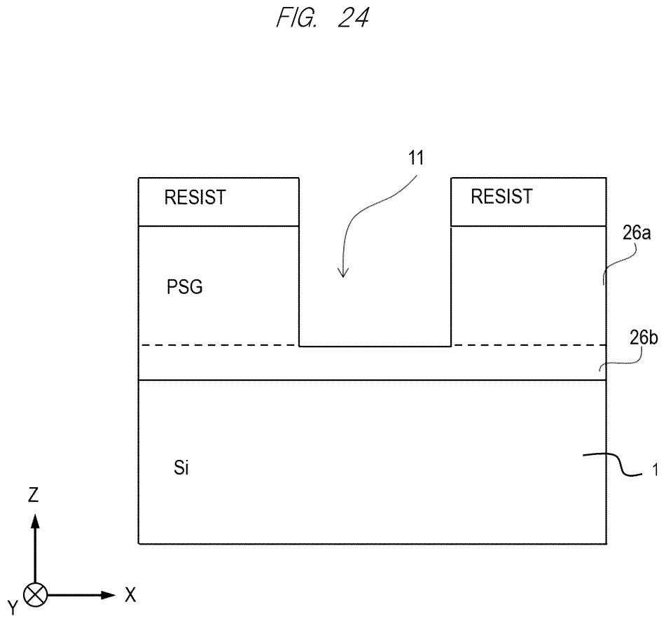

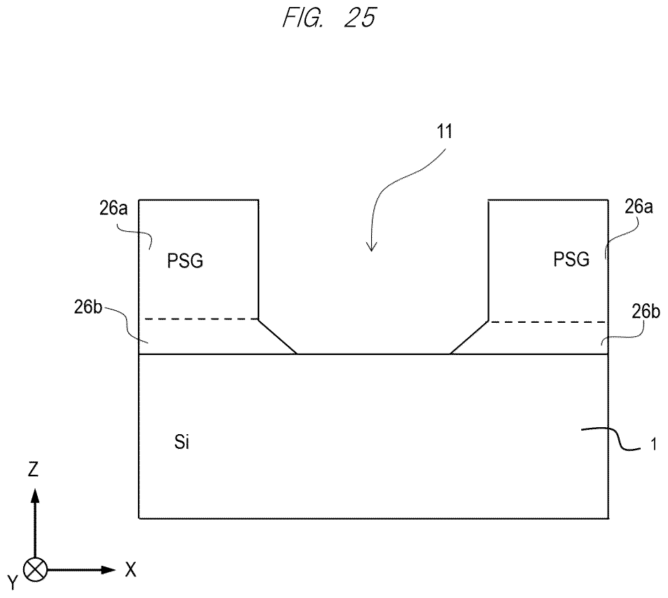

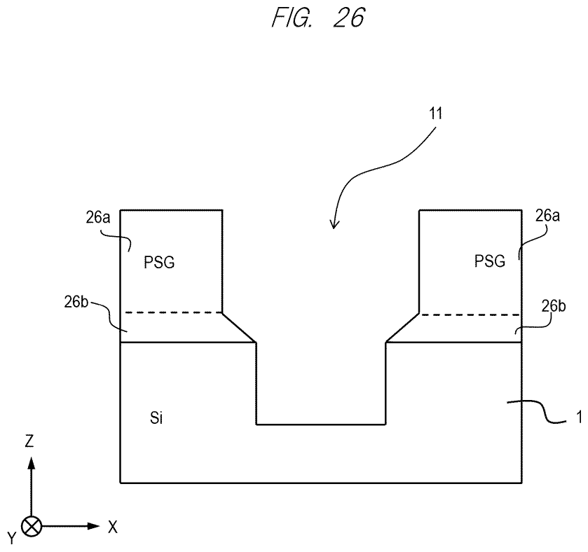

After a resist is applied (FIG. 23) to the semiconductor wafer 1 on which the interlayer insulating film (the upper portion 26a and the lower portion 26b) is formed as illustrated in FIG. 22, photolithography is performed, and an anisotropic oxide film dry etching process is performed to form a contact hole 11 (FIG. 24). This anisotropic oxide film dry etching process is not etched up to the lower portion 26b of the interlayer insulating film but stopped up to the upper portion 26a. As the anisotropic oxide film dry etching gas, for example, a mixed gas including an Ar gas, a CHF₃ gas, a CF₄ gas, an O₂ gas, or the like can be exemplified as a suitable gas. Furthermore, an anisotropic oxide film dry etching process in which etching conditions are changed, such as changing a flow rate ratio of an etching gas (O₂ or the like), is performed on the lower portion 26b of the interlayer insulating film (FIG. 25). The anisotropic dry etching process is also performed on a silicon region to extend the contact hole 11 (FIG. 26). As this anisotropic dry etching gas, for example, Cl₂/O₂ gas can be exemplified as a suitable gas.

### Fourth Embodiment

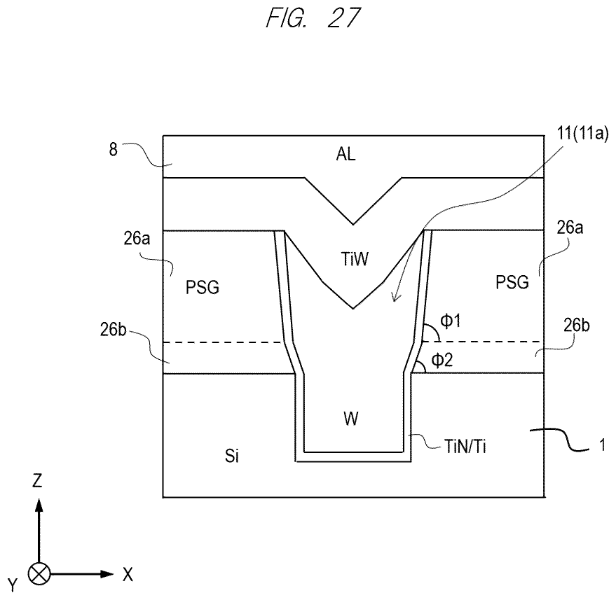

FIG. 27 is a cross-sectional view illustrating a shape of a contact hole according to the fourth embodiment; In a semiconductor device 2 of the fourth embodiment (the plan view is similar to FIG. 1), both the upper portion 26a and the lower portion 26b of the interlayer insulating film are PSG films and are integrated. The shape of a contact hole 11 is similar to that of the second embodiment. In the cross-sectional view, the width of the contact hole 11 in the X direction is wider at an upper end than at a lower end of the contact hole 11, and is wider at a depth corresponding to the upper portion 26a of the interlayer insulating film than at a depth corresponding to the lower portion 26b of the interlayer insulating film. An inclination angle Φ (PHI)1 of the contact hole 11 at the depth corresponding to the upper portion 26a of the interlayer insulating film is larger than an inclination angle Φ (PHI)2 of the contact hole 11 at the depth corresponding to the lower portion 26b. In other words, in the cross-sectional view, the width of the contact hole 11 in the X direction is enlarged at the depth corresponding to the lower portion 26b of the interlayer insulating film and the depth corresponding to the upper portion 26a of the interlayer insulating film in a direction from an inside of the semiconductor wafer 1 toward the front surface 1a (see FIG. 5) along the Z direction, and an enlargement ratio at the depth corresponding to the lower portion 26b of the interlayer insulating film is larger than an enlargement ratio at the depth corresponding to the upper portion 26a of the interlayer insulating film. As described above, the barrier metal film (TiN/Ti) can be thickened and the barrier performance can be enhanced by inclining the upper portion 26a of the interlayer insulating film. Further, by making Φ (PHI)1 larger than Φ (PHI)2, an increase in the contact diameter can be suppressed. Furthermore, unlike the second embodiment, since the interlayer insulating film is a single layer of the PSG film, it is not necessary to switch the film forming conditions in the PSG film forming apparatus, and thus the manufacturing cost is reduced.

### Method of Manufacturing Semiconductor Device in Fourth Embodiment

The method of manufacturing the semiconductor device 2 according to the fourth embodiment is the same as that of the first embodiment except for the steps involved in the formation of the interlayer insulating film and the formation of the contact hole 11. The interlayer insulating film (the upper portion 26a and the lower portion 26b) is formed by forming a PSG film by, for example, a CVD method or the like. Hereinafter, portions relating to the formation of the contact hole 11 different from those in the first embodiment will be described.

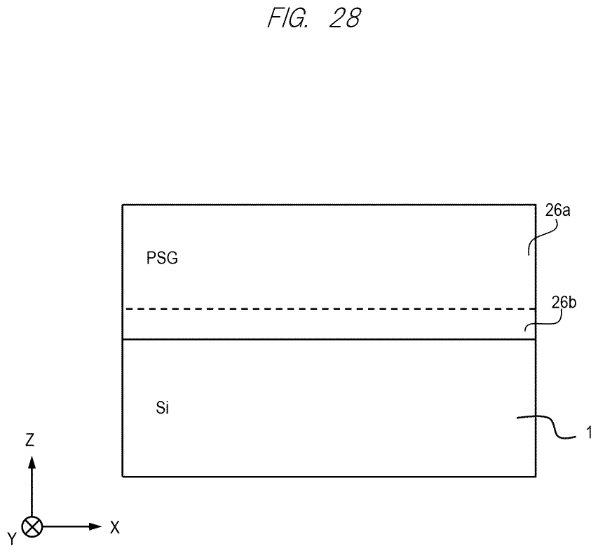

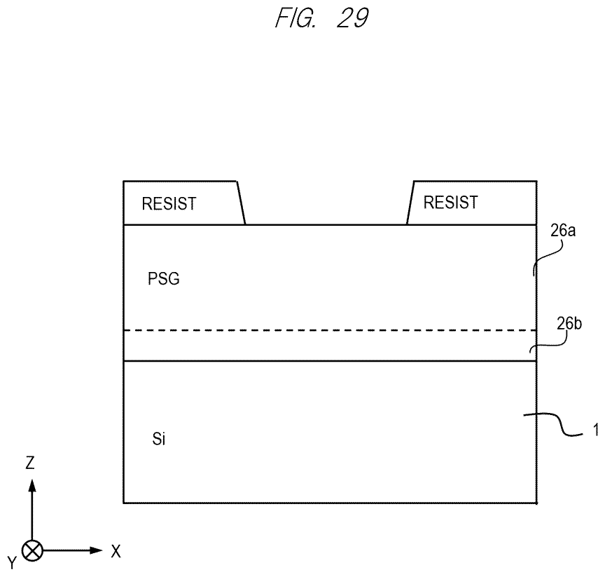

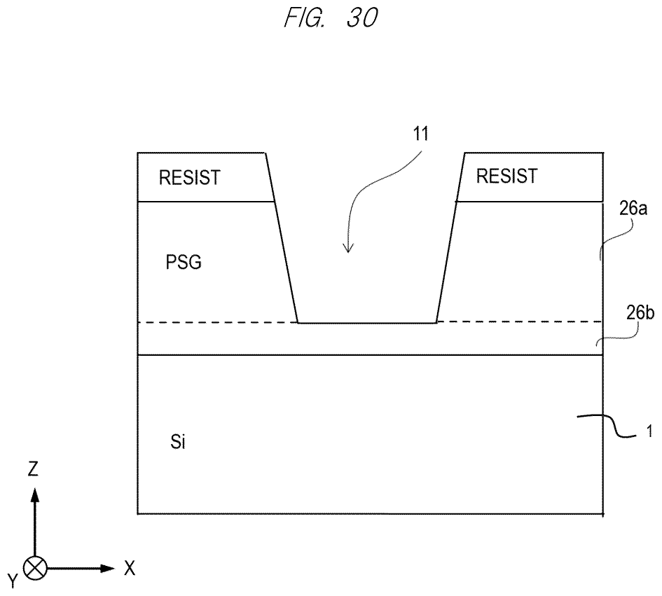

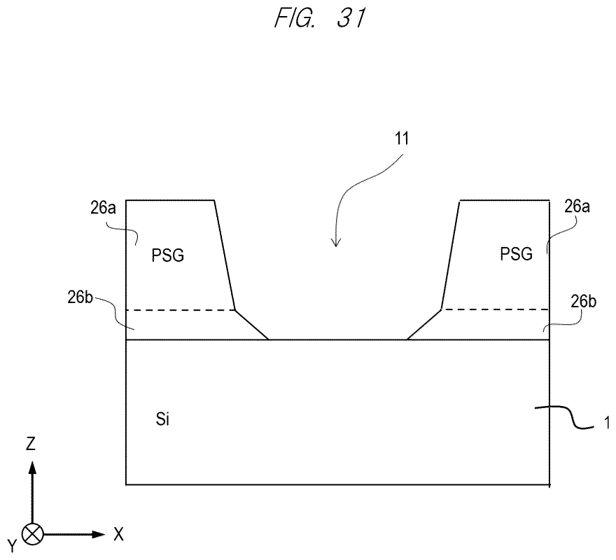

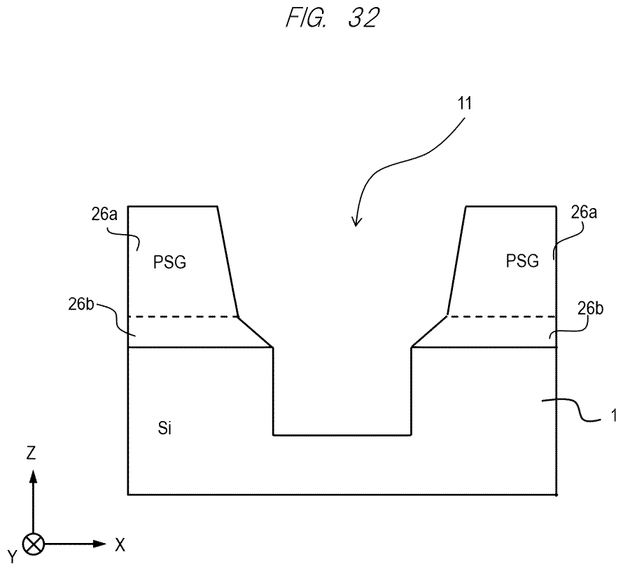

After a resist is applied to the semiconductor wafer 1 on which the interlayer insulating film (the upper portion 26a and the lower portion 26b) is formed as illustrated in FIG. 28 (FIG. 29), photolithography is performed, and anisotropic oxide film dry etching process is performed to form a contact hole 11 (FIG. 30). This anisotropic oxide film dry etching process is not etched up to the lower portion 26b of the interlayer insulating film but stopped up to the upper portion 26a. As the anisotropic oxide film dry etching gas, for example, a mixed gas including an Ar gas, a CHF₃ gas, a CF₄ gas, an O₂ gas, or the like can be exemplified as a suitable gas. Furthermore, an anisotropic oxide film dry etching process in which etching conditions are changed, such as changing a flow rate ratio of an etching gas (O₂ or the like), is performed on the lower portion 26b of the interlayer insulating film (FIG. 31). The anisotropic dry etching process is also performed on a silicon region to extend the contact hole 11 (FIG. 32). As this anisotropic dry etching gas, for example, Cl₂/O₂ gas can be exemplified as a suitable gas.

Although the present invention has been described based on the above embodiments, the present invention is not limited to the above embodiments, and various modifications can be made without departing from the gist of the present invention.

For example, in the above embodiment, the IGBT is exemplified as the device formed in the cell formation region 3, but the technology disclosed in the above embodiment is not limited to the IGBT, and can be applied to any semiconductor device such as a power MOSFET having a vertical trench gate structure.

In addition, the material used for semiconductor substrate SUB is not limited to silicon (Si), and may be silicon carbide (SiC), gallium nitride (GaN), gallium oxide (Ga₂O₃), or the like. The n type impurity may be, for example, phosphorus (P), arsenic (As), or the like, and the p type impurity may be, for example, boron (B), indium (In), or the like.

Further, various configurations described in each embodiment can be implemented in combination with each other. The present specification describes, for example, the following configuration.

### SUPPLEMENTARY NOTES

### Supplementary Note 1

A semiconductor device including:

a semiconductor substrate having a first main surface and having a drift region of a first conductivity type in an inside; and

an interlayer insulating film formed on an upper side of the first main surface and having an upper portion and a lower portion,

the semiconductor device having a cell region in the first main surface in plan view and including, in the cell region:

an active cell region provided from the first main surface to an inside of the drift region;

a trench gate electrode and a trench emitter electrode provided on a front surface of the first main surface so as to be positioned on both sides of the active cell region in a first direction in cross-sectional view, and respectively formed in a pair of trenches including a first trench and a second trench via an insulating film;

a body region of a second conductivity type different from the first conductivity type, the body region being provided in a front surface region of the drift region on a side of the first main surface;

an inactive cell region provided so as to be positioned on both sides of the active cell region in the first direction with the trench gate electrode and the trench emitter electrode as a boundary in cross-sectional view;

an emitter region of the first conductivity type provided in the active cell region and in a front surface region closer to the first main surface than the body region;

a contact member formed in a contact hole penetrating the interlayer insulating film, the contact member being in contact with the trench emitter electrode and the interlayer insulating film on one side in the first direction, and being in contact with the body region, the emitter region, and the interlayer insulating film on another side in the first direction, in cross-sectional view;

a hole barrier region of the first conductivity type provided in the drift region under the body region in the active cell region and having an impurity concentration higher than an impurity concentration of the drift region and lower than an impurity concentration of the emitter region; and

a floating region of the second conductivity type provided under the body region in the inactive cell region, in which

in cross-sectional view, a width of the contact hole in the first direction is wider at an upper end than at a lower end of the contact hole, and is wider at a depth corresponding to the upper portion of the interlayer insulating film than at a depth corresponding to the lower portion of the interlayer insulating film.

### Supplementary Note 2

The semiconductor device according to supplementary note 1, in which

in cross-sectional view, the width of the contact hole in the first direction is enlarged in a direction from an inside of the semiconductor substrate toward the first main surface along a second direction perpendicular to the first direction at each of a depth corresponding to the lower portion of the interlayer insulating film and a depth corresponding to the upper portion of the interlayer insulating film, and an enlargement ratio of the enlargement at the depth corresponding to the lower portion of the interlayer insulating film is larger than an enlargement ratio of the enlargement at the depth corresponding to the upper portion of the interlayer insulating film.

### Supplementary Note 3

The semiconductor device according to supplementary note 1 or 2, in which

compositions of the upper portion and the lower portion of the interlayer insulating film are different from each other.

### Supplementary Note 4

The semiconductor device according to supplementary note 3, in which

the upper portion of the interlayer insulating film is a phospho silicate glass (PSG) film, and the lower portion of the interlayer insulating film is a non-doped silicate glass (NSG) film.

### Supplementary Note 5

The semiconductor device according to supplementary note 1 or 2, in which

the upper portion and the lower portion of the interlayer insulating film form an integrated interlayer insulating film.

### Supplementary Note 6

The semiconductor device according to supplementary note 5, in which

the upper portion and the lower portion of the interlayer insulating film are PSG (phospho silicate glass) films.

### Supplementary Note 7

A method of manufacturing a semiconductor device, including:
(a) preparing a semiconductor substrate having a first main surface and having a drift region of a first conductivity type in an inside;
(b) forming a first trench and a second trench from the first main surface of the semiconductor substrate;
(c) forming an insulating film on the first main surface and an inner wall of each of the first trench and the second trench;
(d) forming a floating region of a second conductivity type on a side of the first main surface of the semiconductor substrate so as to be positioned on both sides of a pair of trenches including the first trench and the second trench in a first direction in cross-sectional view;
(e) forming a hole barrier region of the first conductivity type on the side of the first main surface of the semiconductor substrate so as to be positioned between the first trench and the second trench in cross-sectional view;
(f) forming a trench gate electrode in the first trench via the insulating film and forming a trench emitter electrode in the second trench via the insulating film;
(g) removing the insulating film formed other than insides of the first trench and the second trench;
(h) forming a body region of a second conductivity type in a front surface region of the drift region on the side of the first main surface;
(i) forming an emitter region of the first conductivity type in a front surface region between the trench gate electrode and the trench emitter electrode closer to the side of the first main surface than the body region in cross-sectional view; and
(j) forming an interlayer insulating film having an upper portion and a lower portion on the first main surface; and
(k) forming a contact hole so as to penetrate the interlayer insulating film so that the contact member is in contact with the trench emitter electrode and the interlayer insulating film on one side in the first direction, and is in contact with the body region, the emitter region, and the interlayer insulating film on another side in the first direction in cross-sectional view, and forming the contact member in the contact hole, in which

the (k) includes forming the contact member in the contact hole so that a width of the contact hole in the first direction is wider at an upper end than at a lower end of the contact hole in cross-sectional view and is wider at a depth corresponding to the upper portion of the interlayer insulating film than at a depth corresponding to the lower portion of the interlayer insulating film by etching processing including first etching processing, second etching processing, and third etching processing, and forming the contact member in the contact hole.

### Supplementary Note 8

The method of manufacturing a semiconductor device according to supplementary note 7, in which

compositions of the upper portion and the lower portion of the interlayer insulating film are different from each other.

### Supplementary Note 9

The method of manufacturing a semiconductor device according to supplementary note 8, in which

the upper portion of the interlayer insulating film is a phospho silicate glass (PSG) film, and the lower portion of the interlayer insulating film is a non-doped silicate glass (NSG) film.

### Supplementary Note 10

The method of manufacturing a semiconductor device according to supplementary note 9, in which

the first etching processing and the second etching processing are dry etching processing, and the third etching processing is wet etching processing.

### Supplementary Note 11

The method of manufacturing a semiconductor device according to supplementary note 9, in which the first etching processing, the second etching processing, and the third etching processing are dry etching processing.

### Supplementary Note 12

The method of manufacturing a semiconductor device according to supplementary note 7, in which

the upper portion and the lower portion of the interlayer insulating film form an integrated interlayer insulating film.

### Supplementary Note 13

The method of manufacturing a semiconductor device according to supplementary note 12, in which

the upper portion and the lower portion of the interlayer insulating film are PSG (phospho silicate glass) films.

### Supplementary Note 14

The method of manufacturing a semiconductor device according to supplementary note 13, in which the first etching processing, the second etching processing, and the third etching processing are dry etching processing.

### Supplementary Note 15

A semiconductor device including:

a semiconductor substrate having a first main surface;

an interlayer insulating film formed on an upper side of the first main surface and having an upper portion and a lower portion; and

a contact member formed in a contact hole penetrating the interlayer insulating film, in which

in cross-sectional view, a width of the contact hole in a first direction is wider at an upper end than at a lower end of the contact hole, and is wider at a depth corresponding to the upper portion of the interlayer insulating film than at a depth corresponding to the lower portion of the interlayer insulating film.

What is claimed is:

1. A semiconductor device comprising:
a semiconductor substrate having a first main surface and having a drift region of a first conductivity type in the semiconductor substrate; and
an interlayer insulating film formed on an upper side of the first main surface and having an upper portion and a lower portion,
the semiconductor device having a cell region in the first main surface in plan view and comprising, in the cell region:
an active cell region provided from the first main surface to an inside of the drift region;
a trench gate electrode and a trench emitter electrode provided at a front surface of the first main surface so as to be positioned on both sides of the active cell region in a first direction in cross-sectional view, and respectively formed in a pair of trenches including a first trench and a second trench via an insulating film;
a body region of a second conductivity type different from the first conductivity type, the body region being provided in a front surface region of the drift region on a side of the first main surface;
an inactive cell region provided so as to be positioned on both sides of the active cell region in the first direction with the trench gate electrode and the trench emitter electrode as a boundary in cross-sectional view;
an emitter region of the first conductivity type provided in the active cell region and in a front surface region closer to the first main surface than the body region;
a contact member formed in a contact hole penetrating the interlayer insulating film, the contact member being in contact with the trench emitter electrode and the interlayer insulating film on one side in the first direction, and being in contact with the body region, the emitter region, and the interlayer insulating film on another side in the first direction, in cross-sectional view;
a hole barrier region of the first conductivity type provided in the drift region under the body region in the active cell region and having an impurity concentration higher than an impurity concentration of the drift region and lower than an impurity concentration of the emitter region; and
a floating region of the second conductivity type provided under the body region in the inactive cell region, wherein
in cross-sectional view, a width of the contact hole in the first direction is wider at an upper end than at a lower end of the contact hole, and is wider at a depth corresponding to the upper portion of the interlayer insulating film than at a depth corresponding to the lower portion of the interlayer insulating film.

2. The semiconductor device according to claim 1, wherein
in cross-sectional view, the width of the contact hole in the first direction is enlarged in a direction from an inside of the semiconductor substrate toward the first main surface along a second direction perpendicular to the first direction at each of a depth corresponding to the lower portion of the interlayer insulating film and a depth corresponding to the upper portion of the interlayer insulating film, and an enlargement ratio of the enlargement at the depth corresponding to the lower portion of the interlayer insulating film is larger than an enlargement ratio of the enlargement at the depth corresponding to the upper portion of the interlayer insulating film.

3. The semiconductor device according to claim 1, wherein
compositions of the upper portion and the lower portion of the interlayer insulating film are different from each other.

4. The semiconductor device according to claim 3, wherein
the upper portion of the interlayer insulating film is a phospho silicate glass (PSG) film, and the lower portion of the interlayer insulating film is a non-doped silicate glass (NSG) film.

5. The semiconductor device according to claim 1, wherein
the upper portion and the lower portion of the interlayer insulating film form an integrated interlayer insulating film.

6. The semiconductor device according to claim 5, wherein
the upper portion and the lower portion of the interlayer insulating film are PSG (phospho silicate glass) films.

7. A method of manufacturing a semiconductor device, the method comprising:
(a) preparing a semiconductor substrate having a first main surface and having a drift region of a first conductivity type in the semiconductor substrate;
(b) forming a first trench and a second trench from the first main surface of the semiconductor substrate;
(c) forming an insulating film on the first main surface and an inner wall of each of the first trench and the second trench;
(d) forming a floating region of a second conductivity type on a side of the first main surface of the semiconductor substrate so as to be positioned on both sides of a pair of trenches including the first trench and the second trench in a first direction in cross-sectional view;
(e) forming a hole barrier region of the first conductivity type on the side of the first main surface of the semiconductor substrate so as to be positioned between the first trench and the second trench in cross-sectional view;
(f) forming a trench gate electrode in the first trench via the insulating film and forming a trench emitter electrode in the second trench via the insulating film;
(g) removing the insulating film formed other than insides of the first trench and the second trench;
(h) forming a body region of the second conductivity type in a front surface region of the drift region on the side of the first main surface;
(i) forming an emitter region of the first conductivity type in a front surface region between the trench gate electrode and the trench emitter electrode closer to the side of the first main surface than the body region in cross-sectional view;
(j) forming an interlayer insulating film having an upper portion and a lower portion on the first main surface; and
(k) forming a contact hole so as to penetrate the interlayer insulating film so that a contact member is in contact with the trench emitter electrode and the interlayer insulating film on one side in the first direction, and is in contact with the body region, the emitter region, and the interlayer insulating film on another side in the first direction in cross-sectional view, and forming the contact member in the contact hole, wherein
the (k) includes forming the contact member in the contact hole so that a width of the contact hole in the first direction is wider at an upper end than at a lower end of the contact hole in cross-sectional view and is wider at a depth corresponding to the upper portion of the interlayer insulating film than at a depth corresponding to the lower portion of the interlayer insulating film by etching processing including first etching processing, second etching processing, and third etching processing, and forming the contact member in the contact hole.

8. The method according to claim 7, wherein
compositions of the upper portion and the lower portion of the interlayer insulating film are different from each other.

9. The method according to claim 8, wherein
the upper portion of the interlayer insulating film is a phospho silicate glass (PSG) film, and the lower portion of the interlayer insulating film is a non-doped silicate glass (NSG) film.

10. The method according to claim 9, wherein the first etching processing and the second etching processing are dry etching processing, and the third etching processing is wet etching processing.

11. The method according to claim 9, wherein the first etching processing, the second etching processing, and the third etching processing are dry etching processing.

12. The method according to claim 7, wherein
the upper portion and the lower portion of the interlayer insulating film form an integrated interlayer insulating film.

13. The method according to claim 12, wherein
the upper portion and the lower portion of the interlayer insulating film are PSG (phospho silicate glass) films.

14. The method according to claim 13, wherein the first etching processing, the second etching processing, and the third etching processing are dry etching processing.

15. A semiconductor device comprising:
a semiconductor substrate having a first main surface;
an interlayer insulating film formed on an upper side of the first main surface and having an upper portion and a lower portion; and
a contact member formed in a contact hole penetrating the interlayer insulating film, wherein
in cross-sectional view, a width of the contact hole in a first direction is wider at an upper end than at a lower end of the contact hole, and is wider at a depth corresponding to the upper portion of the interlayer insulating film than at a depth corresponding to the lower portion of the interlayer insulating film.
